(19) United States
(12) Patent Application Publication
(10) Pub. No.: US 2008/0295889 A1
(43) Pub. Date: Dec. 4, 2008

(54) Photovoltaic Module

(75) Inventors: Ulrich Schindler, Furth/Bayern (DE); Michael Heilmann, Forchheim (DE)

Correspondence Address: HOFFMANN & BARON, LLP, 6900 JERICHO TURNPIKE, SYOSSET, NY, 11791, US

(73) Assignee: LEONHARD KURZ STIFTUNG & CO. KG, Furth (DE)

(21) Appl. No.: 12/114,904

(22) Filed: May 5, 2008

(30) Foreign Application Priority Data
May 7, 2007 (DE) 102007021843.7-33

(51) Int. Cl. H01L 31/0256; H01L 31/042; H01L 31/18

(52) U.S. Cl. 136/263; 136/244; 438/73; 438/82; 257/E31.002

(57) ABSTRACT

There is described a photovoltaic module (2) in the form of a multi-layer body with photovoltaic cells (21, 21i) arranged on a carrier layer (20) and having at least one organic polymer-based photoactive layer (213) arranged between a first and a second electrode layer (212, 215), which are electrically connected together in a series circuit. Hole blocker layers (214) and the electron blocker layers (212) in the series circuit of mutually following adjacent photovoltaic cells (21, 21i) are arranged in inverse succession relative to each other with respect to the carrier layer (20). Electrode layers (211, 215), which are electrically connected together by an electrically conducting connecting portion (22), of the mutually following adjacent photovoltaic cells (21, 211) are arranged in a common plane.

The invention concerns a photovoltaic module formed from photovoltaic cells with an organic polymer semiconductor layer or layers.

Photovoltaic cells with photoactive organic polymer-based layers hitherto have levels of efficiency which are in the range of between 3 and 5%. These are levels of efficiency which are markedly lower than those of inorganic solar cells.

If inexpensive manufacturing processes, such as for example the roll-to-roll process, are used for the production of polymer-based flexible solar cells, mass production of solar cells to a considerable extent is conceivable. In order to arrive at solutions which can be used in practice, in that respect a respective plurality of photovoltaic cells have to be combined together to afford modules which, for the respective situation of use, afford an appropriate output voltage and/or an appropriate output current.

Now, the object of the invention is to provide a polymer-based photovoltaic module which is simple to manufacture and which has an improved level of efficiency.

In accordance with the invention that object is attained by the multi-layer body set forth in claim 1 and the process set forth in claim 17. There is proposed a photovoltaic module in the form of a multi-layer body having two or more photovoltaic cells which are arranged on a carrier layer and which are electrically connected together in a series circuit, wherein the photovoltaic cells have a first electrode layer and a second electrode layer and at least one organic polymer-based photoactive layer arranged between a hole blocker layer and an electron blocker layer, wherein it is provided that the hole blocker layers and the electron blocker layers in the series circuit of mutually following adjacent photovoltaic cells are arranged in inverse succession relative to each other with respect to the carrier layer, and that the electrode layers, which are electrically connected together by an electrically conducting connecting portion, of the mutually successive adjacent photovoltaic cells are arranged in a common plane.

In addition there is proposed a process for the production of a photovoltaic module in the form of a multi-layer body having two or more photovoltaic cells connected in series, wherein the photovoltaic cells have a first electrode layer and a second electrode layer and at least one organic polymer-based photoactive layer arranged between a hole blocker layer and an electron blocker layer, wherein it is provided that in the process the further layers are applied to a carrier layer in such a way that the hole blocker layers and the electron blocker layers in the series circuit of mutually following adjacent photovoltaic cells are arranged in inverse succession relative to each other with respect to the carrier layer and that the electrode layers, which are electrically connected together by an electrically conducting connecting portion, of the mutually following adjacent photovoltaic cells are arranged in a common plane.

As will be described in greater detail hereinafter the photoactive layers of the photovoltaic cells of the photovoltaic module according to the invention have semiconducting polymers, in contrast for example to dye cells or Gratzel cells which are constructed on the basis of photoactive dyes so that this involves different operating principles.

By virtue of the provision of adjacent photovoltaic cells which follow each other in the series circuit, with an inverse succession, the cells assume such a position that at least the outside surfaces, that is to say the surfaces of series-connected electrodes, that face away from the photoactive layer, are disposed in one plane and can therefore be connected to an electrical connecting portion extending in that common plane. There is therefore no need for perpendicularly extending connecting portions between adjacent cells which follow each other in the series circuit and which on the one hand limit the usable area of the photovoltaic module and which on the other hand require a manufacturing complication and expenditure which is increased in relation to the solution according to the invention, because they are produced in a plane perpendicular to the layer planes. Different layer thicknesses for the electrode layers do not therefore call the solution according to the invention into question. Photovoltaic cells which follow each other in the series circuit are advantageously in the form of adjacent cells so that particularly simple cell arrangements with a particularly high level of utilisation of surface area are possible.

The photovoltaic module according to the invention can be inexpensively produced in a roll-to-roll process, wherein mutually successive layer applications are involved. In that case each of the layers can be structured in accordance with the requirements concerned, wherein the structuring expressly includes different material being applied region-wise in a layer, for example a layer is formed region-wise from the material provided for the first electrode layer, the material provided for the second electrode layer and the material provided for the connecting portions. In the roll-to-roll process structured layers can be applied by printing for example in accurate register relationship, possibly in a plurality of through-passes. By way of example intaglio printing, ink jet printing or screen printing can be used as the printing processes. It is however also possible to use other application technologies such as spin-on, sputtering or vapor deposition.

If an electrically insulating separating layer is provided between adjacent photovoltaic cells, it can be applied for example by screen printing prior to application of the last electrode layers and the connecting portions. In that case it fills the intermediate spaces between the cells, wherein the contours of the separating layer are determined by the edge contours of the cells. No measures therefore have to be taken for application in accurate register relationship.

Further advantageous configurations are set forth in the appendant claims.

It can advantageously be provided that the layer thicknesses of the layers of the photovoltaic cells are so selected that adjacent layers of mutually following photovoltaic layers are each formed with the same thickness. That gives rise to advantages in the process in terms of production engineering as for example in intaglio printing the anilox application roller is in uniform contact and thus a more regular print is ensured whereas the free configurational option for the photovoltaic cell is only immaterially restricted. Two numerical examples are intended to make that clear: when five layers are involved the first and fifth layers as well as the second and fourth layers are to be produced with the same layer thickness, that is to say, with an odd number of layers, the layers which assume the same position from the central layer are to be formed with the same layer thickness. When six layers are involved the first and the sixth layers, the second and the fifth layers as well as the third and the fourth layers are to be formed with the same layer thickness, that is to say with an even number of layers the layers which are in mutually symmetrical relationship are to be respectively formed with the same layer thickness. In that way it is possible to produce mutually juxtaposed adjacent regions which are arranged in one plane, having regard to thickness tolerances. Advantageously the thickness tolerances should be not more than 50% of the reference or target thickness.

The expression electrode layers which are arranged in a common plane is thus to be interpreted as meaning an arrangement of electrode layers in which a common plane can be laid through the electrode layers. Preferably in that case the top side and/or the underside of the electrodes are respectively disposed in a common plane. It is however also possible that, particularly with different layer thicknesses, the electrodes are not aligned with each other, but the above-described common section plane exists.

It can further be provided that the layers of the photovoltaic cells between the electrodes are formed with similar layer thicknesses (layer thickness variation <20%).

Besides the layers primarily provided for the function of the organic photovoltaic cell, namely electrode layers, blocker layers and a photoactive layer or layers, a further layer or layers can be provided, which for example can provide for better efficiency of the module or the cells. That can involve layers which occupy a fixed position in the composite layer assembly of the photovoltaic cell, like the blocker layers described hereinafter, or which occupy a fixed position in the composite layer assembly of the photovoltaic module. If the latter is the case, the layer or layers does not or do not participate in the inversion, that is to say they respectively form a common plane in the photovoltaic module. This can involve for example a filter layer or a light concentrator layer or the like, which are respectively excluded from the inversion and which occupy a different position in the regular cell and in the inverse cell, in relation to the remaining layers.

The photoactive layer can be made up for example from a mixture of a conjugate polymer acting as a donor such as P3HT (regioregular poly(3-hexylthiophene) or MDMO-PPV [poly(2-methoxy-5-(3-,7-dimethyloctyloxy)-1,4-phenylene vinylene] and fullerenes acting as an acceptor such as C₆₀, or PCBM ([6,6]-phenyl-C₆₁-butric acid methyl ester).

Photoactive layers are also possible, in which both the acceptor and also the donor are made up of semiconductor polymers and which therefore permit particularly inexpensive configurations.

A mixing ratio of between 2:0.5 and 0.5:2 as between the electron donor and the electron acceptor can be preferred.

Furthermore the photoactive layer can also be made up of two mutually superposed layer portions which however must be in the form of very thin layer portions in order to reduce unwanted recombinations of the charge carriers and in order not to unnecessarily increase the resistance in the direction of the surface normal. If the layer portions are very thin then the ability to resist short-circuiting of a photoactive layer made up of layer portions can be less than the above-mentioned mixed layer which is in the form of a relatively thick layer of a thickness of about 100 nm.

In the case of the photoactive layer made up of two mutually superposed layer portions, it is to be provided that, in the case of mutually inverted photovoltaic layers, the orientation of the photoactive layers is inverted, that is to say the layer sequence of the two layer portions is inverted and thus also alternates. Therefore the photoactive layer made up of two layer portions is a polarised photoactive layer and the photoactive layer in the form of a mixed layer is an unpolarised photoactive layer.

The photoactive layer can also involve a matrix structure.

If the electrodes are considered, the first electrode layer can be made up for example of a transparent indium tin oxide layer (ITO) of a layer thickness of between 40 and 150 nm or an ITO-metal-ITO composite of a total layer thickness of 40 nm, and the second electrode layer can comprise a transparent metallic layer, preferably of Ag or Au, of a layer thickness of between 70 and 120 nm, or Cr and Au of a total layer thickness of between 70 and 120 nm, in which respect the Cr-layer serving as a bonding agent can be of a thickness of about 3 nm. ITO forms an anode if the electron blocker layer is applied to the ITO layer. If the hole blocker layer is applied to the ITO layer then the ITO layer forms a cathode.

It can however also be provided that the function of the electron blocker layer and/or the hole blocker layer is afforded by the respective electrode layer and thus the electron blocker layer and/or the hole blocker layer is formed by the respective electrode layer. In that case for example the work functions of the electrodes are responsible for the polarity of the photovoltaic cell. The work functions of the first and second electrode layers should involve a difference which is as large as possible in this case, in order to build up in the photoactive layer a high internal potential which facilitates separation of the charge carriers formed (electrons and holes). A possible combination of materials is for example ITO with a work function of 4.7 eV and aluminum with a work function of 4.3 eV, wherein ITO forms the anode and aluminum forms the cathode.

It can also be provided that the electrode layers disposed in a common plane are not only made from different material because of the inverse layer sequence of adjacent photovoltaic cells connected in the series circuit, for example a transparent ITO layer and a semitransparent metallic layer, but that three or more configurations of the electrode layer alternate, for example in the order transparent ITO layer, semitransparent metallic layer and metallic grating structure. The metallic grating structure can for example at the same time form an electrical contact layer.

It can be provided that an electron blocker layer is arranged between the first electrode layer and the photoactive layer and/or a hole blocker layer is arranged between the second electrode layer and the photoactive layer, or vice-versa. If the electron blocker layer is disposed between the first electrode layer and the photoactive layer, then the first electrode layer is the anode, and if the hole blocker layer is disposed between the second electrode layer and the photoactive layer, then the second photoactive layer is the cathode. The electron blocker layer can be formed for example from PEDOT/PSS (poly(3,4-ethylene dioxythiophene)/polystyrene sulfonate) of a layer thickness of between 50 and 150 nm. The hole blocker layer can be formed for example from TiOₓ of a layer thickness of between 10 and 50 nm. Because the nature of the blocker layers can determine the polarity of the photovoltaic cell it can also be provided that the same material is used for the first and second electrode layers. In that case it can advantageously be provided that the connecting portions are also made from the material of the electrode layers, that affording a particularly simple structure for the photovoltaic module according to the invention.

The two blocker layers can form a unit with the electrode layers and/or at the same time can perform further functions in the photovoltaic cell, for example as a wetting aid and/or as a barrier. If the first electrode layer is for example of ITO, for example a PEDOT/PSS layer can be arranged between the first electrode layer and the photoactive layer. In that example the PEDOT/PSS layer is on the one hand the electron blocker layer and in that case improves wetting of the electrode layer with the photoactive semiconductor layer as the surface tension of the dried PEDOT/PSS layer is very much greater than that of the semiconductor layer which is applied in liquid form. If the second electrode layer is for example in the form of a vapor-deposited silver layer, then a PEDOT/PSS layer applied to the semiconductor layer can act as a barrier for the silver atoms which impinge in the vapor deposition procedure and reduce the probability of short-circuits and/or faulty contacts.

Because of the provided inverse configuration of the layer sequences of the photovoltaic cells, it can be preferred for both blocker layers to be formed with the same layer thickness.

It can be provided that horizontally adjacent photovoltaic cells are of different spectral sensitivity.

It can further be provided that the photovoltaic cells have two or more photoactive layers with different spectral sensitivity. Such cells are also referred to as tandem cells (in the case of a double structure) or generally as multi-junction cells. The fact that the conversion of light energy into electrical energy is provided for more than one spectral range means that the efficiency of the multi-junction cell is increased in relation to a photovoltaic cell with only one photoactive layer. Photovoltaic cells with only one photoactive layer are also referred to as single-junction cells. A plurality of layer sequences of a hole blocker layer, a photovoltaic semiconductor layer and an electron blocker layer, which are disposed between the electrode layers, can be provided to make up multi-junction cells.

The photoactive layers which are produced with different spectral sensitivity can also be of a different structure, as described hereinbefore for single-junction cells.

It can advantageously be provided that for example a layer formed from metallic clusters is introduced between mutually following electron blocker layers and hole blocker layers. The term clusters is used in physics to denote a collection of atoms or molecules, the number of atoms of which is between n=3 and n=50,000.

It is further possible for horizontally adjacent photovoltaic cells to be of a differing width and/or contour. That affords a further configurational option, with the same cell structure. A differing width for the photovoltaic cells can be provided for example in order to adapt cells with various photovoltaic layers in respect of their electrical values, for example the internal resistance.

It can further be provided that the carrier layer is flexible. The carrier layer can be for example in the form of a carrier film of a thickness of between 12 μm and 150 μm. In particular PET, PEN or PVC are considered as the material for same. Combinations thereof are also possible.

It can also be provided that the carrier layer is rigid, for example consisting of glass. A rigid carrier layer can be advantageous in order for example to produce glazings for windows or transparent wall surfaces which can be used at the same time as an energy source.

A further advantageous configuration provides that the carrier layer is uneven and/or is formed with an uneven surface. In that way the carrier layer has a larger surface area than a flat or non-deformed carrier layer so that there is a larger effective area available for generating energy.

It can further be provided that the carrier layer has a coloration. The coloration can for example perform decorative purposes, for example it can be used for the artistic design of window surfaces, or for light filtering. Thus for example a means for protection against the sun can be covered with a photovoltaic module according to the invention which, as described hereinbefore, is in the form of a flexible film body.

It can also be provided that the carrier layer has elements for influencing the passage of light. The carrier layer can for example have light-scattering or light-guiding particles. It can however also have geometrical elements, that is to say for example it can be so shaped that it can focus light.

Further embodiments are directed to the configuration of the electrode layers.

It can be provided that at least one of the electrode layers of the photovoltaic cell is a metallic layer, in particular comprising a metal or an alloy of a plurality of metals. This can involve a homogeneous layer or also a conductive layer with nanoparticles, referred to as clusters.

It can however also be provided that at least one of the electrode layers of the photovoltaic cell is an electrically conducting organic layer. Organic layers can be particularly easily applied by a printing process so that organic layers can be preferred over metallic layers. Doped polyethylene, polyaniline and organic semiconductors have proven their worth for example as electrode layers.

For the purposes of a transparent configuration, that is to say a configuration which is sufficiently radiation-transmissive, it can be provided that electrode layers which face towards the radiation source are in the form of transparent layers, semitransparent layers (metal layers of very small layer thickness), in the form of a grating structure or in the form of a combination of such configurations. The grating structure can preferably be so dimensioned that it is not visible with the naked eye.

Because of the inverse arrangement of adjacent photovoltaic cells of the photovoltaic module according to the invention it is preferred for both electrode layers to be transparent and/or to be formed with a grating structure.

Further embodiments are directed to the production of the photovoltaic module.

It can be provided that the module is in the form of an embossing film or a laminating film or a touchform film or an inmold film.

The photovoltaic module according to the invention can therefore also be used as a semi-manufactured article to produce end products which, besides the main purpose of use, can be used for environmentally friendly solar energy generation. For example vehicle bodies, weather balloons and traffic guidance and management equipment can be formed by means of the specified films and/or coated therewith.

Further advantageous embodiments are directed to the production process.

It can advantageously be provided that the organic photoactive layer is partially applied by a printing process. The layer thickness can advantageously be selected in the range of between 50 nm and 250 nm. The expression partial application is used here and hereinafter to denote that the photoactive layer is not applied over the full surface area but forms a partial layer having regions in which no photoactive material is applied.

It can also be provided that the photoactive layer is firstly applied over the full surface area involved and is then structured, for example by etching or by laser ablation. The regions without photoactive material delimit the photovoltaic cells of the photovoltaic module from each other and can be for example partially or completely filled by an insulating material.

It can further be provided that the hole blocker layer and/or the electron blocker layer is or are partially applied by a printing process. It can however also be provided that the blocker layers are firstly applied over the full surface area involved and then structured or partially removed, as described hereinbefore.

It can therefore be provided that at least one of the layers of the photovoltaic module is applied over the full surface area and then structured by partial removal of the layer.

It can further be provided that the first electrode layer and/or the second electrode layer and/or the connecting portion is or are partially applied by a printing process. If the first and the second electrode layers and the connecting portions are made from the same material of the same layer thickness, it can also be provided that said layers are firstly applied as a layer over the full surface area involved and are then structured or partially removed, as described hereinbefore.

Preferably it can be provided that the layer structure of the photovoltaic module is completely applied by printing, as described hereinbefore.

It can however also be provided that the first electrode layer and/or the second electrode layer and/or the connecting portion is or are applied by vapor deposition or sputtering. That can preferably involve metallic electrodes or inorganic electrodes which are to be produced by sputtering or vapor deposition at a higher quality than by printing on a printing paste mixed with electrode particles.

It is also possible for at least one of the layers of the photovoltaic module to be applied by a lamination process. It is possible for example to use different laminating films which can be combined in different ways and which thus, in particular for small-scale series productions, permit a highly inexpensive solution with a high quality in the end product.

It can further be provided that the photovoltaic module is laminated into an arrangement. In particular, film-based photovoltaic modules can be very easily laminated into an arrangement and thus can be reliably protected from environmental influences such as moisture and atmospheric oxygen which limit the service life.

The invention will now be described in greater detail with reference to the drawings in which:

FIG. 1 shows a diagrammatic view in section of a photovoltaic module in accordance with the state of the art,

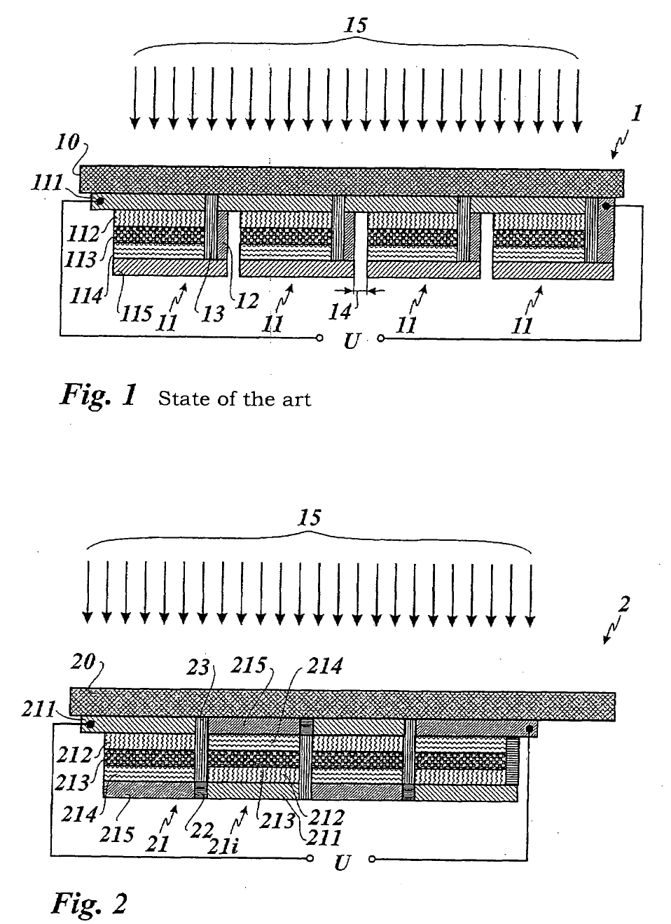

FIG. 2 shows a diagrammatic view in section of a first embodiment of the photovoltaic module according to the invention, and

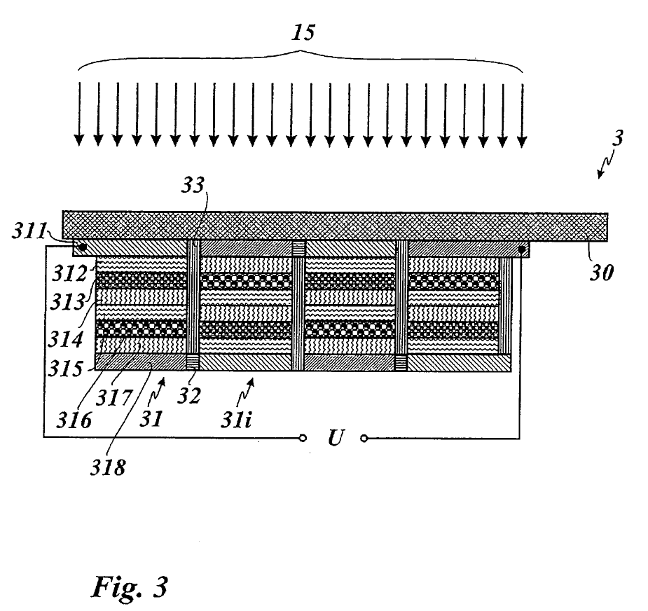

FIG. 3 shows a diagrammatic view in section of a second embodiment of the photovoltaic module according to the invention.

FIG. 1 shows a photovoltaic module 1 in accordance with the state of the art which is in the form of a multi-layer body and which provides a terminal voltage U at contact surfaces accessible from the exterior, when it is exposed to light, for example sunlight.

Arranged on a carrier layer 10 are photovoltaic cells 11 of the kind of what is referred to as single-junction cells which are connected together in a series circuit. The carrier layer can be for example a PET film of a thickness of between about 20 and 25 μm.

The photovoltaic cells 11 comprise layers arranged one above the other, more specifically a first electrode layer 111 applied directly to the carrier layer 10 and facing towards incident light beams 15, an electron blocker layer 112, an organic photoactive layer 113, a hole blocker layer 114 and a second electrode layer 115. Two photovoltaic cells 11 which follow each other in the series circuit are electrically conductingly connected together by electrically conductive connecting portions 12 arranged perpendicularly on the carrier layer 10, wherein in each case the second electrode layer 115 of the preceding photovoltaic cell 11 is connected to the first electrode layer 111 of the subsequent photovoltaic cell 11. The connecting portion 12 is electrically insulated from the photovoltaic cell 11 by a separating portion 13. The separating portion 13 is arranged at a narrow side of the photovoltaic cell 11. It can be for example an electrically insulating adhesive layer or a hardenable insulator, for example a two-component system of epoxy resin and hardener. The connecting portion 12 is separated from the subsequent photovoltaic cell by an air gap 14. Instead of the air gap 14 it would also be possible to provide an insulating layer filling the gap space. The photoactive layers involve layers of polymer type as described in greater detail hereinafter with reference to FIG. 2.

In the regions of the connecting portion 12, the separating portion 13 and the air gap 14 the light beams 15 impinging on the photovoltaic module 1 do not contribute to energy generation and therefore reduce the effectiveness of the photovoltaic module 1.

FIG. 2 now shows a first embodiment of a photovoltaic module 2 according to the invention with a carrier layer 20, the module differing from the photovoltaic module 1 in accordance with the state of the art as shown in FIG. 1 in that photovoltaic cells which follow each other are formed with an inverse layer sequence.

A photovoltaic layer 21 which precedes in the series circuit, starting from the carrier layer 20, has a first electrode layer 211, an electron blocker layer 212, an organic photoactive layer 213, a hole blocker layer 214 and a second electrode layer 215. A photovoltaic cell 21i which follows the photovoltaic cell 21 in the series circuit has an inverse layer sequence, that is to say now the second electrode layer 215 is arranged on the carrier layer 20 and the first electrode layer 211 is the uppermost layer of the photovoltaic cell 21i, facing away from the carrier film 20. Consequently the blocker layers have also exchanged places in the inverse cell.

The first electrode layer 211 can be in the form of a transparent indium tin oxide layer (ITO) of a layer thickness of between 10 and 15 nm, and the second electrode layer 215 can be formed from a semitransparent metallic layer, for example silver, gold or chromium/gold, of a layer thickness of between 10 and 30 nm. The second electrode layer however can also be in the form of a grating of the above metals or metal combinations, wherein now the metallic regions can be of thicknesses which are preferably up to 120 nm. The photoactive layer 213 can for example be made up of a mixture of conjugate polymer acting as a donor such as P3HT (regioregular poly(3-hexylthiophene) or MDMO-PPV [poly(2-methoxy-5-(3-, 7-dimethyloctyloxy)-1,4-phenylene vinylene], and fullerenes acting as an acceptor such as C₆₀ or PCBM ([6,6]-phenyl-C₆₁-butric acid methyl ester).

In the FIG. 2 embodiment in the preferred metal pairing the first electrode layer 211 is the anode, that is to say the positive pole, and the second electrode layer 215 is the cathode, that is to say the negative pole of the photovoltaic cells 21, 21i.

It can also be provided that one or both of the blocker layers 212, 213 are omitted. By way of example a PEDOT/PSS layer can be provided as an electron blocker layer only between the first electrode layer 211 of ITO and the photoactive layer 213. With such an arrangement care is to be taken to ensure that the photoactive layers 213 of adjacent cells 21, 21i are not arranged in a common plane. If the photoactive layers 213 are further in the form of a layer system comprising two mutually superposed layer portions of p-semiconductor type and of n-semiconductor type respectively, care is to be taken to ensure that that layer sequence must also be inverted.

In the FIG. 2 embodiment the two electrode layers 211, 215 are of equal layer thickness so that the electrode layers of the adjacent photovoltaic cells 21, 21i are in one plane. They can therefore be electrically conductingly connected together directly by an electrically conductive connecting portion 22 which is preferably of the same thickness as the two electrode layers 211, 215. For electrical separation between the two adjacent photovoltaic cells 21, 21i, there is a separating portion 23 arranged perpendicularly on the carrier layer 20. The separating portion 23 can be for example in the form of an adhesive layer or can be formed by a hardenable system, for example a two-component system.

The photovoltaic cell 21i involves the same layer structure as the photovoltaic cell 21, but with the inverse layer sequence.

On the assumption that the three elements referred to in FIG. 1 and masking the light incidence, namely the connecting portion 12, the separating portion 13 and the air gap 14, are of the same thickness as the separating portion 23 shown in FIG. 2, in the photovoltaic module 2 according to the invention (FIG. 2) the shadowing region is reduced in relation to the photovoltaic module 1 in accordance with the state of the art (FIG. 1) to ⅓rd. That procedure means that the geometrical filling factor of the module—also referred to as the GFF—is increased.

FIG. 3 shows a photovoltaic module 3 with what is referred to as tandem cells. A tandem cell comprises two photovoltaic cells with different photoactive material, which are in mutually superposed layered relationship. A first electrode layer 311 is followed by a first electron blocker layer 312, a first photoactive layer 313, a first hole blocker layer 314, a second electron blocker layer 315, a second photoactive layer 316, a second hole blocker layer 317 and a second electrode layer 318. One or more layer or layers (not shown in FIG. 4) can be arranged between the first hole blocker layer 314 and the second electron blocker layer 315.

The photovoltaic module 3 therefore utilises the energy of the incident light in a wide spectral range and therefore has a higher level of efficiency than the photovoltaic module 2 with only one photoactive layer, described hereinbefore with reference to FIG. 2.

The electrode layers in the aforementioned embodiments are preferably transparent or semitransparent, wherein the respective electrode layer facing away from the light entrance side can also be semitransparent or non-transparent.

The first and second electrode layers 211 and 215, 311 and 318 respectively (FIG. 2 and FIG. 3) can also be made from the same material, for example silver, gold or chromium/gold. Advantageously the connecting portions 22 and 32 respectively may also be made from the unitary electrode material so that adjacent electrode layers together with the connecting portions electrically connecting them can form a common region, thereby affording a particularly simple structure for the modules 2 and 3 respectively.

Because the individual layers of the photovoltaic modules according to the invention have thicknesses in the nanometer range, at a maximum in the micrometer range, those modules can be deformed virtually as desired so that for example they can also be shaped into hoses or can be fitted on to hoses. Photovoltaic modules in hose form, by virtue of a medium flowing through the hoses, for example water, can use the residual energy present in the form of heat energy of the light, by the medium being fed to a heat pump or a heat exchanger.

Semiconductor solar cells are generally connected to form large solar modules for energy generation. For that purpose the cells are connected in series with conductor tracks at the front side and the rear side. As a result the voltages of the individual cells are added and it is possible to use thinner wires for the circuitry than in the case of a parallel circuit. However additional protection diodes (bypass diodes) must be fitted in parallel with the cells as protection from avalanche breakdown in the individual cells (for example in the event of partial shading), which diodes can bridge over cells affected by shading.

1. A photovoltaic module in the form of a multi-layer body having two or more photovoltaic cells which are arranged on a carrier layer and which are electrically connected together in a series circuit, wherein the photovoltaic cells have a first electrode layer and a second electrode layer and at least one organic polymer-based photoactive layer arranged between a hole blocker layer and an electron blocker layer, wherein
the hole blocker layers and the electron blocker layers in the series circuit of mutually following adjacent photovoltaic cells are arranged in inverse succession relative to each other with respect to the carrier layer, and wherein electrode layers, which are electrically connected together by an electrically conducting connecting portion, of the mutually following adjacent photovoltaic cells are arranged in a common plane.

2. A photovoltaic module as set forth in claim 1, wherein the layer thicknesses of the layers of the photovoltaic cells are so selected that adjacent layers of mutually following photovoltaic layers are each formed with the same thickness.

3. A photovoltaic module as set forth in claim 2, wherein the layers of the photovoltaic cells are of the same layer thickness.

4. A photovoltaic module as set forth in claim 1, wherein photovoltaic cells which follow each other in the series circuit are formed with an inverse layer sequence.

5. A photovoltaic module as set forth in claim 1, wherein horizontally adjacent photovoltaic cells have photoactive layers with different spectral sensitivity.

6. A photovoltaic module as set forth in claim 1, wherein the photovoltaic cells respectively have two or more photoactive layers of different spectral sensitivity.

7. A photovoltaic module as set forth in claim 1, wherein horizontally adjacent photovoltaic cells are of differing width and/or contour.

8. A photovoltaic module as set forth in claim 1, wherein the carrier layer has a coloration.

9. A photovoltaic module as set forth in claim 1, wherein the carrier layer has elements influencing the light passage.

10. A photovoltaic module as set forth in claim 1, wherein at least one of the electrode layers of the photovoltaic cells is a metallic layer.

11. A photovoltaic module as set forth in claim 1, wherein at least one of the electrode layers of the photovoltaic cells is an electrically conducting organic layer.

12. A photovoltaic module as set forth in claim 1, wherein at least one of the electrode layers of the photovoltaic cells is semitransparent and/or comprises a material structured in grating form.

13. A photovoltaic module as set forth in claim 1, wherein the module is in the form of an embossing film.

14. A photovoltaic module as set forth in claim 1, wherein the module is in the form of a laminating film.

15. A photovoltaic module as set forth in claim 1, wherein the module is in the form of a touchform film.

16. A photovoltaic module as set forth in claim 1, wherein the module is in the form of an inmold film.

17. A process for the production of a photovoltaic module in the form of a multi-layer body having two or more photovoltaic cells connected in series, wherein the photovoltaic cells have a first electrode layer and a second electrode layer and at least one organic polymer-based photoactive layer arranged between a hole blocker layer and an electron blocker layer, wherein
in the process the further layers are applied to a carrier layer in such a way that the hole blocker layers and the electron blocker layers in the series circuit of mutually following adjacent photovoltaic cells are arranged in inverse succession relative to each other with respect to the carrier layer and wherein the electrode layers, which are electrically connected together by an electrically conducting connecting portion, of the mutually following adjacent photovoltaic cells are arranged in a common plane.

18. A process for the production of a photovoltaic module as set forth in claim 17, wherein the organic photoactive layer is partially applied by a printing process.

19. A process for the production of a photovoltaic module as set forth in claim 17, wherein the hole blocker layer and/or the electron blocker layer is or are partially applied by a printing process.

20. A process for the production of a photovoltaic module as set forth in claim 17, wherein the first electrode layer and/or the second electrode layer and/or the connecting portion is or are partially applied by a printing process.

21. A process for the production of a photovoltaic module as set forth in claim 17, wherein the first electrode layer and/or the second electrode layer and/or the connecting portion is or are applied by vapor deposition or sputtering.

22. A process for the production of a photovoltaic module as set forth in claim 17, wherein at least one of the layers of the photovoltaic module is applied by a lamination process.

23. A process for the production of a photovoltaic module as set forth in claim 17, wherein at least one of the layers of the photovoltaic module is applied over the full surface area involved and is then structured by partial removal of the layer.
